(19) United States
(12) Patent Application Publication
(10) Pub. No.: US 2026/0182231 A1
(43) Pub. Date: Jun. 25, 2026

(54) Organic Light Emitting Display Device

(71) Applicant: LG Display Co., Ltd., Seoul (KR)

(72) Inventors: Kyung Kook Jang, Paju-si (KR); Seong Han Hwang, Paju-si (KR); Won Rae Kim, Paju-si (KR); June Hwan Kim, Paju-si (KR)

(21) Appl. No.: 19/390,546

(22) Filed: Nov. 15, 2025

(30) Foreign Application Priority Data
Dec. 20, 2024 (KR) 10-2024-0192336

(51) Int. Cl. H10K 59/80; H10K 59/122

(52) U.S. Cl. CPC H10K 59/8792; H10K 59/122; H10K 59/873

(57) ABSTRACT

An organic light emitting display device is disclosed in the present specification. The disclosed specification includes: a substrate; a circuit element layer disposed on the substrate; a plurality of pixel defining films disposed on the circuit element layer; a plurality of light emitting elements disposed between the plurality of pixel defining films and having a first electrode and a light emitting layer, and a second electrode; an encapsulation layer disposed on the second electrode of the plurality of light emitting elements; a black matrix disposed on the encapsulation layer and overlapping the pixel defining films; and a plurality of color filter layers disposed between the black matrix. The plurality of pixel defining films include a plurality of light absorbing portions.

### CROSS-REFERENCE TO RELATED APPLICATION

This application claims priority to and the benefit of Republic of Korea Patent Application No. 10-2024-0192336, filed Dec. 20, 2024, the disclosure of which is incorporated herein by reference in its entirety.

### BACKGROUND

### Field

The present specification relates to an organic light emitting display device.

### Discussion of Related Art

Electroluminescent display devices may be classified into inorganic light emitting display devices and organic light emitting display devices according to the material of the light emitting layer.

An active matrix type organic light emitting display device includes an organic light emitting diode (hereinafter referred to as “OLED”) that emits light by itself, and has advantages of fast response speed, high luminous efficiency, high luminance, and large viewing angle. In the organic light emitting display device, OLEDs are formed in each of the pixels. The organic light emitting display device not only has fast response speed and excellent luminous efficiency, luminance, and viewing angle, but also has excellent contrast ratio and color reproduction rate because it can express black grayscale as complete black.

### SUMMARY

The problem to be solved according to an embodiment of the present specification is to provide an organic light emitting display device that is capable of blocking reflection by applying a light absorbing color material as a pixel defining film for pixel separation so that light introduced from the outside and transmitted through the color filter layer is absorbed by the light absorbing portions.

The problems to be solved according to embodiments of the present specification are not limited to the problems mentioned above, and other problems not mentioned will be clearly understood by those skilled in the art from the description below.

An organic light emitting display device according to an embodiment of the present specification includes: a substrate; a circuit element layer disposed on the substrate; a plurality of pixel defining films disposed on the circuit element layer; a plurality of light emitting elements disposed between the plurality of pixel defining films and having a first electrode, a light emitting layer, and a second electrode; an encapsulation layer disposed on the second electrode of the plurality of light emitting elements; a black matrix disposed on the encapsulation layer and overlapping the pixel defining film; and a plurality of color filter layers disposed between the black matrix, wherein the plurality of pixel defining films may include a plurality of light absorbing portions.

An organic light emitting display device according to another embodiment of the present specification includes: a substrate having a plurality of sub-pixel regions; a plurality of light emitting elements disposed on the substrate located in the plurality of sub-pixel regions; and a plurality of pixel defining films separating the plurality of light emitting elements, wherein the plurality of pixel defining films may include a plurality of light absorbing portions.

Specific details according to various examples of the present specification other than the above-mentioned means for solving the problem are included in the description and drawings below.

According to the present specification, by applying selective light absorbing portions as pixel defining films for each sub-pixel, light transmitted through the color filter layer of the color on encapsulation (CoE) structure is absorbed by the pixel defining film, thereby blocking light reflection and enabling Deep Black technology implementation.

The effects of the present specification are not limited to the effects mentioned above, and other effects not mentioned will be clearly understood by those skilled in the art to which the technical idea of the present specification belongs from the description below.

### BRIEF DESCRIPTION OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is a schematic plan view of a plurality of sub-pixels of an organic light emitting display device according to an embodiment of the present specification;

FIG. 2 is a plan view showing a first light absorbing portion of a pixel defining film in an organic light emitting display device according to an embodiment of the present specification;

FIG. 3 is a plan view showing a first light absorbing portion and a second light absorbing portion of a pixel defining film in an organic light emitting display device according to an embodiment of the present specification;

FIG. 4 is a plan view showing a first light absorbing portion, a second light absorbing portion, and a third light absorbing portion of a pixel defining film in an organic light emitting display device according to an embodiment of the present specification;

FIG. 5 is a cross-sectional view taken along line I-I′ of FIG. 1, showing a cross-section of an organic light emitting display device according to an embodiment of the present specification;

FIG. 6 is a graph showing transmittance by wavelength of R, G, B color layers in an organic light emitting display device according to an embodiment of the present specification;

FIG. 7 is a cross-sectional view of a red sub-pixel region in an organic light emitting display device according to another embodiment of the present specification;

FIG. 8 is a graph showing transmittance by wavelength in a pixel defining film (cyan portion) composed of green and blue light absorbing portions disposed on the side of the red sub-pixel region in an organic light emitting display device according to another embodiment of the present specification;

FIG. 9 is a cross-sectional view of a green sub-pixel region in an organic light emitting display device according to another embodiment of the present specification;

FIG. 10 is a graph showing transmittance by wavelength in a pixel defining film (magenta portion) composed of red and blue light absorbing portions disposed on the side of the green sub-pixel region in an organic light emitting display device according to another embodiment of the present specification;

FIG. 11 is a cross-sectional view of a blue sub-pixel region in an organic light emitting display device according to another embodiment of the present specification;

FIG. 12 is a graph showing transmittance by wavelength of a pixel defining film (yellow portion) composed of red and green light absorbing portions in an organic light emitting display device according to another embodiment of the present specification;

FIG. 13 is a schematic plan view of a plurality of sub-pixels of an organic light emitting display device according to another embodiment of the present specification;

FIG. 14 is a plan view showing a first light absorbing portion of a pixel defining film in an organic light emitting display device according to another embodiment of the present specification;

FIG. 15 is a plan view showing a first light absorbing portion and a second light absorbing portion of a pixel defining film in an organic light emitting display device according to another embodiment of the present specification;

FIG. 16 is a plan view showing a first light absorbing portion, a second light absorbing portion, and a third light absorbing portion of a pixel defining film in an organic light emitting display device according to another embodiment of the present specification; and

FIG. 17 is a cross-sectional view taken along line II-II′ of FIG. 13, showing a cross-section of an organic electroluminescent display device according to another embodiment of the present specification.

### DETAILED DESCRIPTION OF EXEMPLARY EMBODIMENTS

The advantages and features of the present specification, and methods of achieving them will be apparent from the embodiments described in detail below in conjunction with the accompanying drawings. However, the present specification is not limited to the following embodiments disclosed herein, but may be implemented in various different forms; rather, the present embodiments are provided to make the disclosure of the present specification complete and to enable those skilled in the art to fully comprehend the scope of the present specification.

The shapes, sizes, proportions, angles, numbers, and the like of elements shown in the drawings to illustrate embodiments of the present specification are merely illustrative and are not intended to be limiting. Identical reference numerals may designate identical components throughout the description. Further, in describing the present specification, detailed descriptions of related known technologies may be omitted so as not to obscure the essence of the present specification. The terms such as “including,” “having,” and “consisting of” as used herein are generally intended to allow other components to be added unless the terms are used with the term “only.” References to components of a singular noun include the plural of that noun, unless specifically stated otherwise.

In the interpretation of components, they are construed to include margins of error, even if not explicitly stated.

When describing a positional relationship, for example, “on top of,” “above,” “below,” “next to,” or “adjacent to” describes the positional relationship of two parts, one or more other parts may be located between the two parts, unless “immediately,” “directly,” or “near to” is used.

When describing a temporal relationship, “after,” “subsequently to,” “following,” or “before” describes a temporal antecedent or consequent relationship, which may not be continuous unless “immediately,” or “directly” is used.

The first, the second, and so on are used to describe various components, but these components are not limited by these terms. These terms are used only to distinguish one component from another. Therefore, a first component referred to below may be a second component within the technical spirit of the present disclosure.

Terms such as first, second, A, B, (a), or (b) may be used to describe elements of the embodiments of the present specification. Such terms are intended only to distinguish one component from another and are not intended to define the nature, sequence, order, or number of such components.

When a component is described as being “connected,” “coupled”, “accessed,” or “attached” to another component, it is to be understood that the component may be directly connected, coupled, accessed, or attached to the other component, but that there may also be other components interposed between the respective components which may be indirectly connected, coupled, accessed, or attached, unless specifically stated otherwise.

When a component is described as being “in contact” or “overlapping” with another component, it is to be understood that the component may be in direct contact or overlap with the other component, but other components may also be “interposed” between these components, resulting in indirect contact or overlap, unless specifically stated otherwise.

It should be understood that the term “at least one” includes all possible combinations of one or more related components. For example, the meaning of “at least one of the first, second, and third components” may be understood to include not only the first, second, or third component, but also any combination of two or more of the first, second, and third components.

The terms “the first direction,” “the second direction,” “the third direction,” “the X-axis direction,” “the Y-axis direction,” and “the Z-axis direction” are not to be interpreted solely as a geometric relationship in which the relationship to one another is perpendicular, but may refer to a broader range of orientations in which the configurations of the present specification may function.

As used herein, a device may include a display device, such as a liquid crystal module (LCM) or an organic light-emitting display (OLED) module, which includes a display panel and a driver for driving the display panel. It may also include a set electronic apparatus or a set device, such as a laptop computer, a television set, a computer monitor, a vehicle or an automotive apparatus, or an equipment apparatus including another form of vehicle, and a mobile electronic apparatus, such as a smart phone or an electronic pad and the like, which is a complete product or finished product including LCMs, OLED modules, and the like.

Therefore, the device in the present specification may include a display device itself, such as an LCM module, OLED module, and the like, and a set device which is an application product or an end-consumer device including the LCM, OLED module, and the like.

Furthermore, in some embodiments, an LCM module and an OLED module composed of a display panel and a driver may be expressed as a display device, and an electronic device as a finished product including the LCM, OLED module (or panel) may be distinguished and expressed as a set device.

For example, the display device may include a liquid crystal display (LCD) panel or an organic light-emitting diode (OLED) display panel, and a source printed circuit board (PCB) which is a control part for driving the display panel. The set device may further include a set PCB, which is a set control part electrically connected to the source PCB to drive the entire set device.

The display panels used in the embodiments of the present specification may be any type of display panels such as a liquid crystal display panel, an organic light-emitting diode (OLED) display panel, and an electroluminescent display panel, but the embodiments are not limited thereto. For example, the display panel may be a display panel capable of generating sound by being vibrated by a vibration device according to the embodiments of the present specification. The display panel applied to the display device according to the embodiments of the present specification is not limited to the form or size of the display panel.

Each of the features of various embodiments of the present specification may be coupled or combined with one another in whole or in part, and may be technologically interlocked and operated in various ways, and each of the embodiments may be carried out independently or in conjunction with one another.

Hereinafter, various embodiments of the present specification will be described in detail with reference to the accompanying drawings. The scale of the components shown in the drawings has a different scale from the actual scale for convenience of explanation and is not limited to the scale shown in the drawings.

Various display devices such as organic electroluminescent display devices, electrophoretic display devices, mini light-emitting diode (LED) display devices, and micro LED display devices may be applied to the display device of the present specification, but hereinafter, for convenience of explanation, organic electroluminescent display devices will be described as an example.

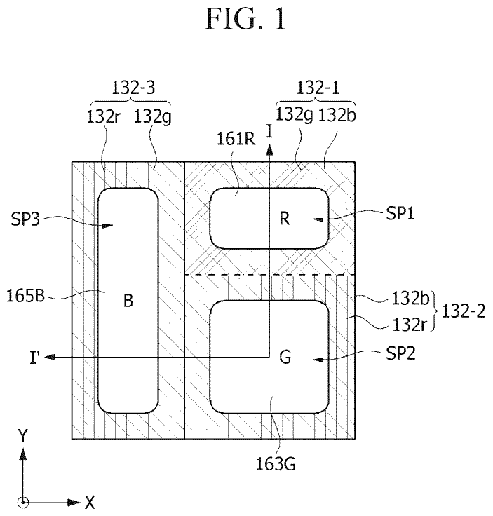

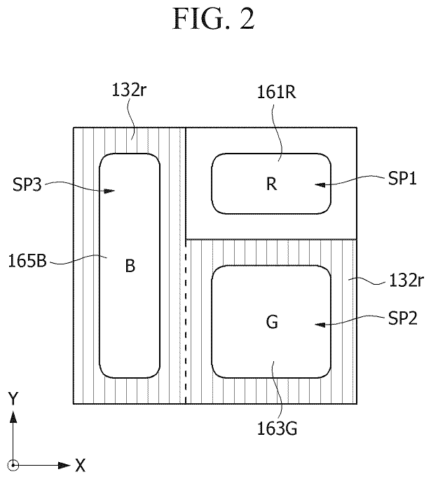

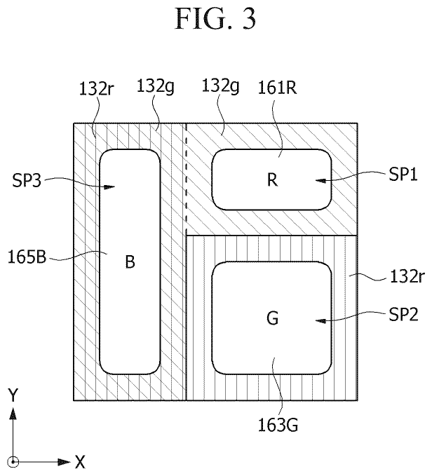

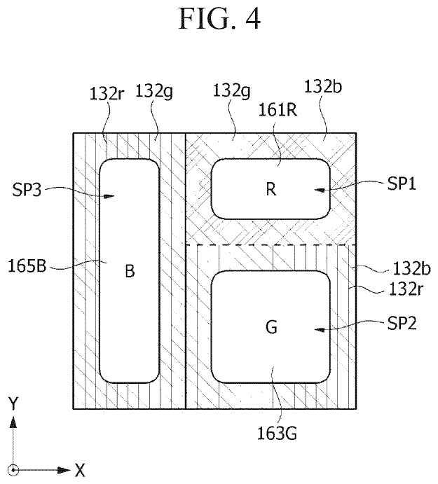

FIG. 1 is a schematic plan view of a plurality of sub-pixels of an organic light emitting display device according to an embodiment of the present specification. FIG. 2 is a plan view showing a first light absorbing portion of a pixel defining film in an organic light emitting display device according to an embodiment of the present specification. FIG. 3 is a plan view showing a first light absorbing portion and a second light absorbing portion of a pixel defining film in an organic light emitting display device according to an embodiment of the present specification. FIG. 4 is a plan view showing a first light absorbing portion, a second light absorbing portion, and a third light absorbing portion of a pixel defining film in an organic light emitting display device according to an embodiment of the present specification.

Referring to FIGS. 1 to 4, an organic light emitting display device according to an embodiment of the present specification may include a plurality of sub-pixels SP1, SP2, and SP3 and first to third pixel defining films 132-1, 132-2, and 132-3 provided in boundary regions between the plurality of sub-pixels SP1, SP2, and SP3.

The plurality of sub-pixels SP1, SP2, and SP3 may include a first sub-pixel SP1 arranged in a first direction, for example, the X-axis direction, a second sub-pixel SP2 arranged in a second direction, for example, the Y-axis direction, adjacent to the first sub-pixel SP1, and a third sub-pixel SP3 arranged in the first direction, for example, the X-axis direction, adjacent to the first sub-pixel SP1 and the second sub-pixel SP2.

The plurality of sub-pixels SP1, SP2, and SP3 form one unit pixel and may be repeatedly arranged in the first direction and the second direction. However, the arrangement structure of the plurality of sub-pixels SP1, SP2, and SP3 may be changed to various forms known in the art.

In the first sub-pixel SP1, light of a first color, for example, red may be emitted, in the second sub-pixel SP2, light of a second color, for example, green may be emitted, and in the third sub-pixel SP3, light of a third color, for example, blue may be emitted.

Referring to FIGS. 1 to 5, the first pixel defining film 132-1 may be located between a red light emitting element 130R and a green light emitting element 130G. The first pixel defining film 132-1 may include a third light absorbing portion 132b and a first light absorbing portion 132r and a second light absorbing portion 132g disposed between the third light absorbing portion 132b and a planarization layer 129. The first light absorbing portion 132r may refer to a red light absorbing portion, the second light absorbing portion 132g may refer to a green light absorbing portion, and the third light absorbing portion 132b may refer to a blue light absorbing portion.

Referring to FIGS. 1 to 5, the second pixel defining film 132-2 may be located between the green light emitting element 130G and the blue light emitting element 130B. The second pixel defining film 132-2 may include a first light absorbing portion 132r and a second light absorbing portion 132g and a third light absorbing portion 132b stacked on the first light absorbing portion 132r.

Referring to FIGS. 1 to 5, the third pixel defining film 132-3 may be located between the blue light emitting element 130B and the red light emitting element 130R. The third pixel defining film 132-3 may include a first light absorbing portion 132r and the third light absorbing portion 132b, and a second light absorbing portion 132g stacked on the first light absorbing portion 132r and the third light absorbing portion 132b.

Here, each of the first to third pixel defining films 132-1, 132-2, and 132-3 may include three first to third light absorbing portions 132r, 132g, and 132b. However, in the present specification, each of the first to third pixel defining films 132-1, 132-2, and 132-3 is not limited thereto.

The first to third pixel defining films 132-1, 132-2, and 132-3 are provided in boundary regions between the plurality of sub-pixels SP1, SP2, and SP3 to define individual sub-pixel SP1, SP2, and SP3 regions.

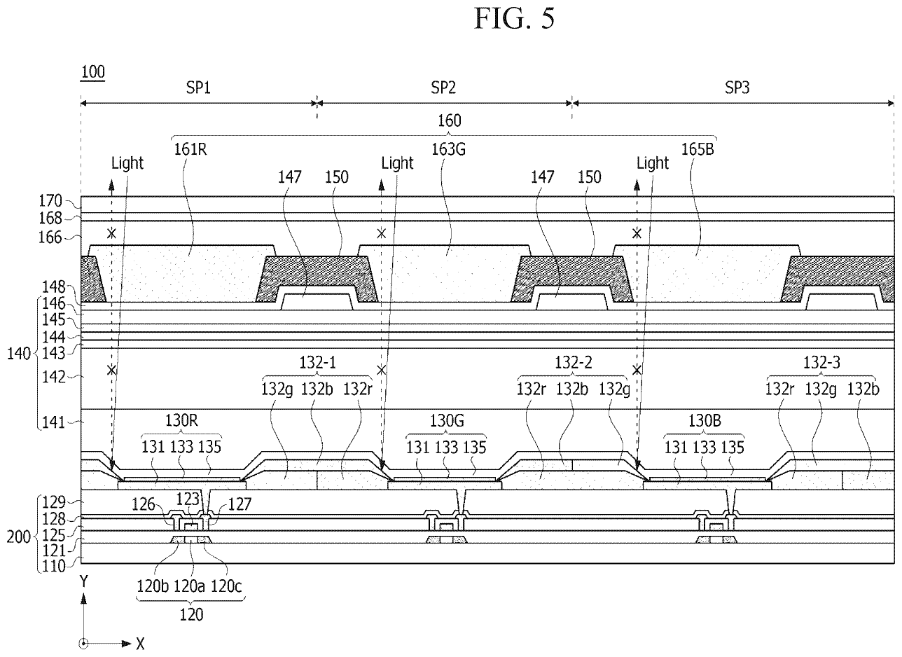

FIG. 5 is a cross-sectional view taken along line I-I′ of FIG. 1, showing a cross-section of an organic light emitting display device according to an embodiment of the present specification.

Referring to FIG. 5, an organic light emitting display device 100 according to an embodiment of the present specification may include a substrate 110, a circuit element layer 200, a plurality of light emitting elements 130, a pixel defining film 132, an encapsulation layer 140, a black matrix 150, a color filter layer 160, and a cover glass 170.

The substrate 110 may be made of glass or transparent plastic, but is not necessarily limited thereto, and may also be made of a semiconductor material such as a silicon wafer.

In the case where the organic light emitting display device according to an embodiment of the present specification is configured as a top emission method, not only transparent materials but also opaque materials may be used as the material of the substrate 110. However, in the case where the organic light emitting display device according to an embodiment of the present specification is configured as a bottom emission method, transparent materials may be used as the material of the substrate 110.

The circuit element layer 200 may be formed on the substrate 110. The circuit element layer 200 may include a driving thin film transistor.

The driving thin film transistor may include an active layer 120 provided on the substrate 110, a gate insulating film 121 provided on the active layer 120, and a gate electrode 123 provided on the gate insulating film 121. The active layer 120 may include a channel region 120a, a source region 120b, and a drain region 120c.

Although the driving thin film transistor is illustrated as having a top gate structure with an interlayer insulating film 125 provided on the gate electrode 123, and provided on the interlayer insulating film 125 and disposed over the active layer 120 through holes provided in the interlayer insulating film 125 and the gate insulating film 121, the present specification may include a driving thin film transistor having a bottom gate structure in which the gate electrode 123 is provided below the active layer 120.

The circuit element layer 200 may further include a passivation layer 128 and a planarization layer 129 provided on the driving thin film transistor. The passivation layer 128 is provided on the source electrode 126 and the drain electrode 127, and the planarization layer 129 may be provided on the passivation layer 128.

The passivation layer 128 and the planarization layer 129 have contact holes, and the first electrode 131 may be connected to the drain electrode 127 through the contact holes. In some cases, the first electrode 131 may be connected to the source electrode 126 through the contact holes.

The first electrode 131 may be disposed on the planarization layer 129. The first electrode 131 may be disposed to correspond to each of the plurality of sub-pixels SP1, SP2, and SP3. The first electrode 131 is a component for supplying holes to the light emitting layer 133 and may be formed of a conductive material with a high work function. The first electrode 131 may be a transparent conductive layer formed of transparent conductive oxide (TCO). For example, the first electrode 131 may be formed of one or more selected from transparent conductive oxides such as indium-tin-oxide (ITO), indium-zinc-oxide (IZO), indium-tin-zinc oxide (ITZO), tin oxide (SnO₂), zinc oxide (ZnO), indium-copper-oxide (ICO), and aluminum-doped zinc oxide (Al-doped ZnO, AZO), but is not limited thereto.

The circuit element layer 200 may further include various signal wires including gate wires, data wires, power wires, and reference wires, various thin film transistors including switching thin film transistors and sensing thin film transistors, and capacitors, in addition to the driving thin film transistor.

The switching thin film transistor may be switched according to a gate signal supplied to the gate wire to supply a data voltage supplied from the data wire to the driving thin film transistor.

The driving thin film transistor may be switched according to the data voltage supplied from the switching thin film transistor to generate a data current from the power supplied through the power wire and supply it to the first electrode 131.

The sensing thin film transistor serves to sense the threshold voltage deviation of the driving thin film transistor that causes image quality degradation, and may supply the current of the driving thin film transistor to the reference wire in response to a sensing control signal supplied from the gate wire or a separate sensing wire.

The capacitor serves to maintain the data voltage supplied to the driving thin film transistor during one frame, and may be connected to the gate terminal and source terminal of the driving thin film transistor.

Each of the switching thin film transistor, driving thin film transistor, and sensing thin film transistor may be changed to various structures known in the art, such as bottom gate structure or top gate structure.

The circuit element layer 200 may further include a passivation layer and a planarization layer provided on the passivation layer to protect the switching thin film transistor, driving thin film transistor, and sensing thin film transistor.

Referring to FIG. 5, the first electrode 131 may function as an anode of the electroluminescent display device, and may be patterned on each of the plurality of sub-pixels SP1, SP2, and SP3, and may be surrounded by the first to third pixel defining films 132-1, 132-2, and 132-3.

The first to third pixel defining films 132-1, 132-2, and 132-3 are provided in boundary regions between the plurality of sub-pixels SP1, SP2, and SP3 to define individual sub-pixel SP1, SP2, and SP3 regions.

A first electrode 131 may be formed for each sub-pixel SP1, SP2, and SP3 on the circuit element layer 200. The first electrode 131 may function as an anode of the organic light emitting display device.

Such a first electrode 131 may include a transparent electrode when the organic light emitting display device according to the present specification is a bottom emission type. When the organic light emitting display device according to the present specification is a top emission type, it may include a reflective electrode.

The pixel defining film 132 is formed to cover both ends of the first electrode 131 on the circuit element layer 200 and may be formed at boundaries between the plurality of sub-pixels SP1, SP2, and SP3.

The pixel defining film 132 may include first to third pixel defining films 132-1, 132-2, and 132-3. Here, the first to third pixel defining films 132-1, 132-2, and 132-3 may be formed by applying red, green, and blue color absorbing materials. However, the present specification is not limited thereto.

The first pixel defining film 132-1 may be located between the red light emitting element 130R and the green light emitting element 130G. The first pixel defining film 132-1 may include a third light absorbing portion 132b and a first light absorbing portion 132r and a second light absorbing portion 132g disposed between the third light absorbing portion 132b and a planarization layer 129.

The first light absorbing portion 132r may refer to a red light absorbing portion, the second light absorbing portion 132g may refer to a green light absorbing portion, and the third light absorbing portion 132b may refer to a blue light absorbing portion. Here, the first light absorbing portion 132r may be formed using a red color absorbing material. The second light absorbing portion 132g may be formed using a green color absorbing material. The third light absorbing portion 132b may be formed using a blue color absorbing material.

The second pixel defining film 132-2 may be located between the green light emitting element 130G and the blue light emitting element 130B. The second pixel defining film 132-2 may include a first light absorbing portion 132r and a second light absorbing portion 132g and a third light absorbing portion 132b stacked on the first light absorbing portion 132r.

The third pixel defining film 132-3 may be located between the blue light emitting element 130B and the red light emitting element 130R. The third pixel defining film 132-3 may include a first light absorbing portion 132r and the third light absorbing portion 132b, and a second light absorbing portion 132g stacked on the first light absorbing portion 132r and the third light absorbing portion 132b.

Here, each of the first to third pixel defining films 132-1, 132-2, and 132-3 may include three first to third light absorbing portions 132r, 132g, and 132b. However, in the present specification, each of the first to third pixel defining films 132-1, 132-2, and 132-3 is not limited thereto.

The first to third pixel defining films 132-1, 132-2, and 132-3 are provided in boundary regions between the plurality of sub-pixels SP1, SP2, and SP3 to define individual sub-pixel SP1, SP2, and SP3 regions.

A light emitting layer 133 may be formed on the first electrode 131 located in the plurality of sub-pixels SP1, SP2, and SP3. The light emitting layer 133 may include a red light emitting layer 133r located in the first sub-pixel SP1, a green light emitting layer 133g located in the second sub-pixel SP2, and a blue light emitting layer 133b located in the third sub-pixel SP3.

Here, the first sub-pixel SP1 is a red sub-pixel, the second sub-pixel SP2 is a green sub-pixel, and the third sub-pixel SP3 may be a blue sub-pixel.

The light emitting layer 133 is disconnected from each other for each of the first to third sub-pixels SP1, SP2, and SP3 by the first to third pixel defining films 132-1, 132-2, and 132-3.

The light emitting layer 133 may include a hole injection layer (HIL), a hole transport layer (HTL), an emission material layer (EML), an electron transport layer (ETL), and an electron injection layer (EIL).

The light emitting layer 133 may include a red light emitting layer 133r, a green light emitting layer 133g, and a blue light emitting layer 133b. The red light emitting layer 133r is located in the red sub-pixel SP1 region, the green light emitting layer 133g is located in the green sub-pixel SP2 region, and the blue light emitting layer 133b may be located in the blue sub-pixel SP3 region.

The red light emitting layer 133r may refer to a light emitting layer of an organic material that emits red light. The green light emitting layer 133g may refer to a light emitting layer of an organic material that emits green light. The blue light emitting layer 133b may refer to a light emitting layer of an organic material that emits blue light.

A second electrode 135 may be formed on the pixel defining film 132 and the light emitting layer 133. The second electrode 135 may be formed to be continuous without being disconnected in the entire internal region and boundary region of the plurality of sub-pixels SP1, SP2, and SP3.

The second electrode 135 may be formed of a metal material with a low work function to smoothly supply electrons to the light emitting layer 133. For example, the second electrode 135 may be formed of a metal material selected from calcium (Ca), barium (Ba), aluminum (Al), silver (Ag), and alloys containing one or more of these materials, but is not limited thereto.

The second electrode 135 may be formed as one layer on the first electrode 131. That is, the second electrode 135 may be formed as a single layer in the sub-pixels SP1, SP2, and SP3. When the organic light emitting display device 100 is driven in a top emission method, the second electrode 135 may be formed with a very thin thickness to become substantially transparent.

The second electrode 135 may function as a cathode of the electroluminescent display device. Such a second electrode 135 may be composed of a transparent electrode or semi-transparent electrode when the organic light emitting display device according to the present specification is a top emission type. When the organic light emitting display device according to the present specification is a bottom emission type, it may be composed of a reflective electrode.

An encapsulation layer 140 may be formed on the second electrode 135. The encapsulation layer 140 may serve to prevent external moisture or oxygen from penetrating into the organic light emitting element 130.

The encapsulation layer 140 may include a first passivation layer 141, a first organic insulating layer 142, a second passivation layer 143, a lower buffer layer 144, an insulating material layer 145, and a second organic insulating layer 146. However, the present specification is not limited thereto.

In this configuration, the first passivation layer 141 and the second passivation layer 143 may each be independently formed of one or more selected from silicon nitride (SiNx), silicon oxide (SiOx), aluminum oxide (AlOx), and silicon oxynitride (SiON), but are not limited thereto.

The first and second organic insulating layers 142 and 146 may be formed of one or more selected from acrylic resin, epoxy resin, polyimide, polyethylene, and silicon oxycarbide (SiOC), but are not limited thereto.

The lower buffer layer 144 may be formed of an inorganic insulating material, for example, one or more selected from silicon nitride (SiNx), silicon oxide (SiOx), aluminum oxide (AlOx), and silicon oxynitride (SiON), but is not limited thereto.

A touch electrode 147 may be formed on the second organic insulating layer 146. The touch electrode 147 may be formed at a position overlapping with the pixel defining film 132.

A second buffer layer 148 covering the touch electrode 147 may be formed on the second organic insulating layer 146. The second buffer layer 148 may be formed of an inorganic insulating material, for example, one or more selected from silicon nitride (SiNx), silicon oxide (SiOx), aluminum oxide (AlOx), and silicon oxynitride (SiON), but is not limited thereto.

A black matrix 150 may be formed on the second buffer layer 148 located in regions excluding the sub-pixel SP1, SP2, and SP3 regions. The black matrix 150 may be formed in regions between each of the red color filter layer, green color filter layer, and blue color filter layer, for example, in boundary regions between the plurality of sub-pixels SP1, SP2, and SP3. The black matrix 150 may include opening portions that expose each of the red color filter layer, green color filter layer, and blue color filter layer.

The black matrix 150 may function as an anti-reflection layer that maintains high brightness of light emitted from the organic light emitting element 130 while absorbing external light to minimize deterioration of visibility and contrast ratio of the organic light emitting display device 100 due to external light.

The black matrix 150 may absorb external light. Accordingly, deterioration of visibility and contrast ratio of the organic light emitting display device 100 due to external light may be minimized. The black matrix 150 may include a base resin and a black material. The base resin may be one or more selected from cardo-based resin, epoxy-based resin, acrylate-based resin, siloxane-based resin, and polyimide, but is not limited thereto. The black material may be a black pigment selected from carbon-based pigments, metal oxide-based pigments, and organic-based pigments. For example, the carbon-based pigment may be carbon black. For example, the metal oxide-based pigment include titanium black (TiNxOy), Cu—Mn—Fe-based black pigments, etc., but are not limited thereto. For example, the organic-based pigment may be selected from lactam black, perylene black, and aniline black, but is not limited thereto. Also, RGB black pigments including red pigments, blue pigments, and green pigments may be used as black materials, but are not limited thereto.

A color filter layer 160 may be disposed in the opening portion of the black matrix 150, for example, on the second buffer layer 148 located in regions of the plurality of sub-pixels.

The color filter layer 160 may include a transparent base resin and a color-development material. For example, the transparent base resin may be one selected from polyacrylate, polymethyl methacrylate, polyimide, polyvinyl alcohol, polyethylene, polypropylene, polystyrene, polyethylene terephthalate, etc., but is not limited thereto. The color-development material absorbs light in a specific wavelength band and transmits light in other wavelength bands. For example, a red color filter may include a red color-development material that transmits light in the red wavelength band and absorbs light in the green and blue wavelength bands.

The color filter layer 160 may include a red color filter layer 161R provided in the first sub-pixel SP1, a green color filter layer 163G provided in the second sub-pixel SP2, and a blue color filter layer 165B provided in the third sub-pixel SP3.

An overcoat layer 166 covering the color filter layer 160 may be formed on the black matrix 150. The overcoat layer 166 may serve to protect internal components from external impact.

The overcoat layer 166 may planarize the upper portions of the plurality of color filter layers 161R, 163G, and 165B and the black matrix 150. For example, the overcoat layer 166 may be formed of transparent resins such as acrylic resin, silicone resin, polyester resin, epoxy resin, etc., but is not limited thereto.

A cover glass 170 may be disposed on the overcoat layer 166.

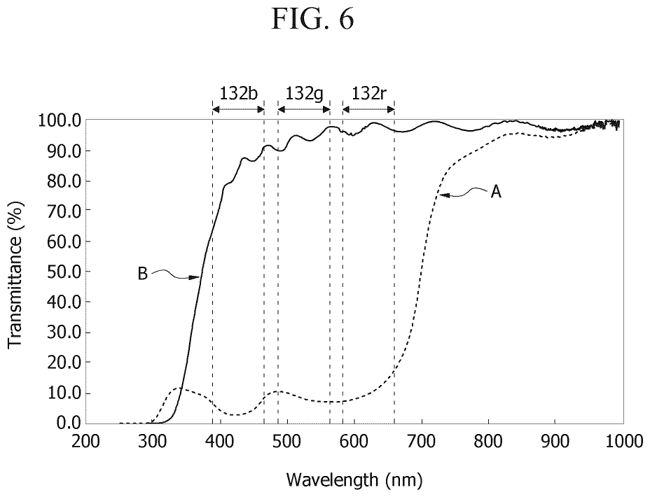

FIG. 6 is a graph showing transmittance by wavelength of R, G, and B color layers in an organic light emitting display device according to an embodiment of the present specification.

Referring to “A” in FIG. 6, when applying a conventional black pixel defining film, light incident into the interior through the color filter layer 160 is reflected to adjacent sub-pixel regions without passing through the black pixel defining film, thereby reducing color reproduction rate in adjacent sub-pixels.

Referring to “B” in FIG. 6, in the present specification, light incident into the interior through the color filter layer 160 is transmitted and absorbed at the ends of the red light absorbing portion 132r, green light absorbing portion 132g, and blue light absorbing portion 132b, which are the stacked structure of the transparent pixel defining film 132, thereby reducing the reflection ratio. That is, since the pixel defining film 132 is composed of the red light absorbing portion 132r, green light absorbing portion 132g, and blue light absorbing portion 132b, when external light comes into contact with the red light absorbing portion 132r, green light absorbing portion 132g, and blue light absorbing portion 132b constituting the pixel defining film 132, it is transmitted and absorbed, thereby reducing the ratio of light reflected externally.

For example, referring to FIG. 6, it can be seen that in the red color filter layer 161R in the wavelength range of 580 to 650 nm, the transmittance increases to about 95% or more, but the reflectance decreases to about 10% or less at the side portion of the pixel defining film 132 located in the boundary region of the red color filter layer 161R.

Referring to FIG. 6, it can be seen that in the green color filter layer 163G in the wavelength range of 500 to 580 nm, the transmittance increases to about 90% or more, but the reflectance decreases to about 8% or less at the side portion of the pixel defining film 132 located in the boundary region of the green color filter layer 163G.

Referring to FIG. 6, it can be seen that in the blue color filter layer 163B in the wavelength range of 380 to 480 nm, the transmittance increases to about 80% or more, but the reflectance decreases to about 5% or less at the side portion of the pixel defining film 132 located in the boundary region of the blue color filter layer 163B.

Therefore, in the present specification, some of the light incident from the outside is transmitted and absorbed into the pixel defining film 132 without being reflected to adjacent sub-pixel regions through the side edges of the red light absorbing portion 132r, green light absorbing portion 132g, and blue light absorbing portion 132b of the pixel defining film 132 located in the boundary region of the sub-pixels SP1, SP2, and SP3, thereby improving color reproduction rate in the sub-pixel regions SP1, SP2, and SP3.

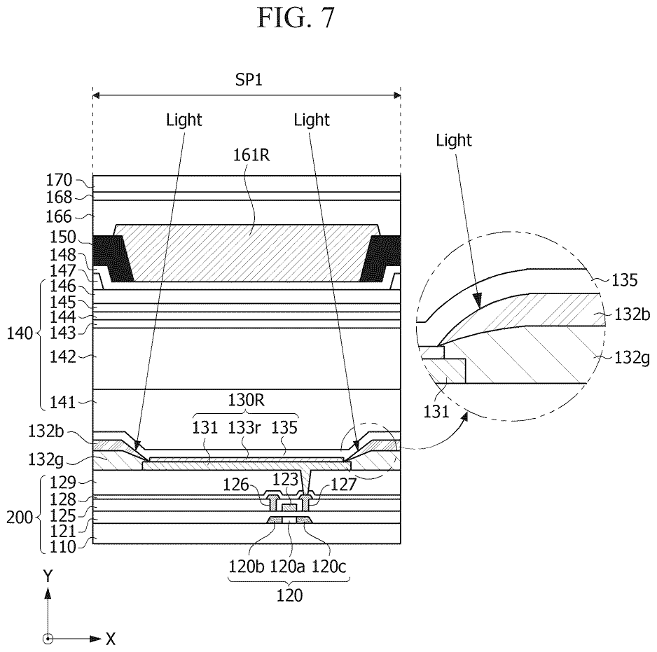

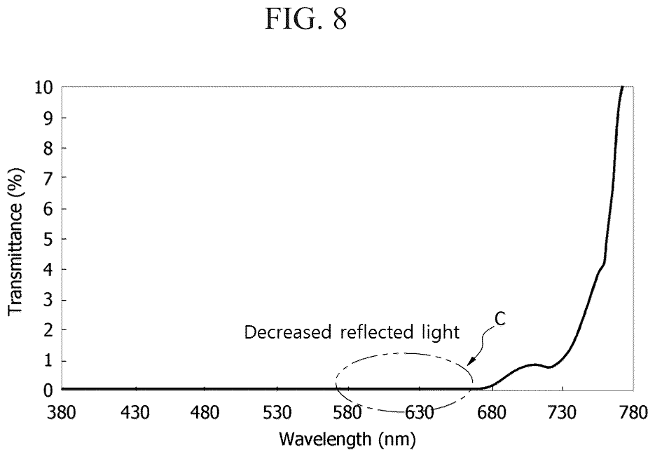

FIG. 7 is a cross-sectional view of a red sub-pixel region in an organic light emitting display device according to another embodiment of the present specification. FIG. 8 is a graph showing transmittance by wavelength in a pixel defining film composed of green and blue light absorbing portions disposed on the side of the red sub-pixel region in an organic light emitting display device according to another embodiment of the present specification.

Referring to FIG. 7, first and third pixel defining films 132-1 and 132-3 may contact both sides of the red light emitting layer 133r below the red color filter layer 161R located in the first sub-pixel SP1.

In this regard, the portions of the first pixel defining film 132-1 and third pixel defining film 132-3 in contact with both ends of the red light emitting layer 133r may include a green light absorbing portion 132g and a blue light absorbing portion 132b. The green light absorbing portion 132g and blue light absorbing portion 132b may be configured in a vertically stacked structure. For example, the blue light absorbing portion 132b may be disposed on the green light absorbing portion 132g.

Referring to FIGS. 7 and 8, light incident through the red color filter layer 161R proceeds to the red light emitting element 130R region and may be transmitted to the first pixel defining film 132-1 and third pixel defining film 132-3 located at the side edges of the red light emitting layer 133r. In this case, some of the light transmitted through the red color filter layer 161R contacts the blue light absorbing portion 132b and is not reflected from it but transmitted and absorbed into the blue light absorbing portion 132b and green light absorbing portion 132g.

Referring to FIG. 8, it can be confirmed that reflected light is reduced as no peak wavelength for transmittance value appears in the red wavelength range of 580 to 680 nm.

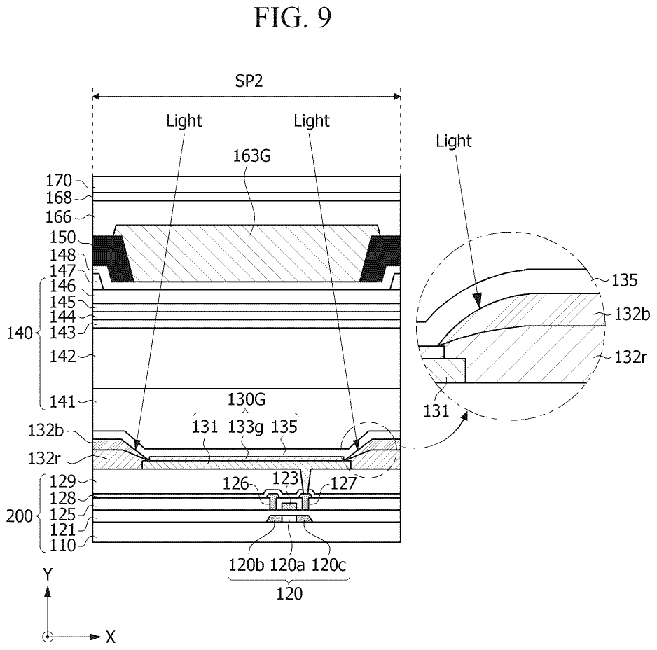

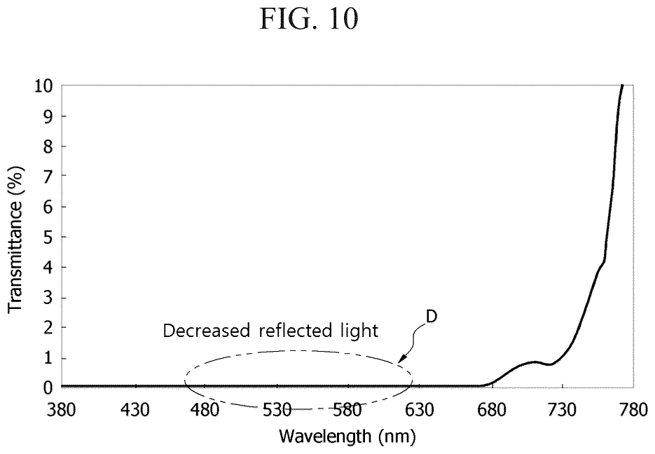

FIG. 9 is a cross-sectional view of a green sub-pixel region in an organic light emitting display device according to another embodiment of the present specification. FIG. 10 is a graph showing transmittance by wavelength in a pixel defining film (magenta portion) composed of red and blue light absorbing portions disposed on the side of the green sub-pixel region in an organic light emitting display device according to another embodiment of the present specification.

Referring to FIG. 9, first and second pixel defining films 132-1 and 132-2 may contact both sides of the green light emitting layer 133g below the green color filter layer 163G located in the second sub-pixel SP2.

In this regard, the portions of the first pixel defining film 132-1 and second pixel defining film 132-2 in contact with the ends of the green light emitting layer 133g may include a red light absorbing portion 132r and a blue light absorbing portion 132b. The red light absorbing portion 132r and blue light absorbing portion 132b may be configured in a vertically stacked structure. That is, the blue light absorbing portion 132b may be disposed on the red light absorbing portion 132r.

Referring to FIGS. 9 and 10, light incident through the green color filter layer 163G proceeds to the green light emitting element 130G region and may be transmitted to the first pixel defining film 132-1 and second pixel defining film 132-2 located at the side edges of the green light emitting layer 133g. In this case, some of the light incident through the green color filter layer 163G contacts the blue light absorbing portion 132b and is not reflected from it but transmitted and absorbed into the blue light absorbing portion 132b and red light absorbing portion 132r.

Referring to FIG. 10, it may be confirmed that reflected light is reduced as no peak wavelength for transmittance value appears in the green wavelength range of 480 to 580 nm.

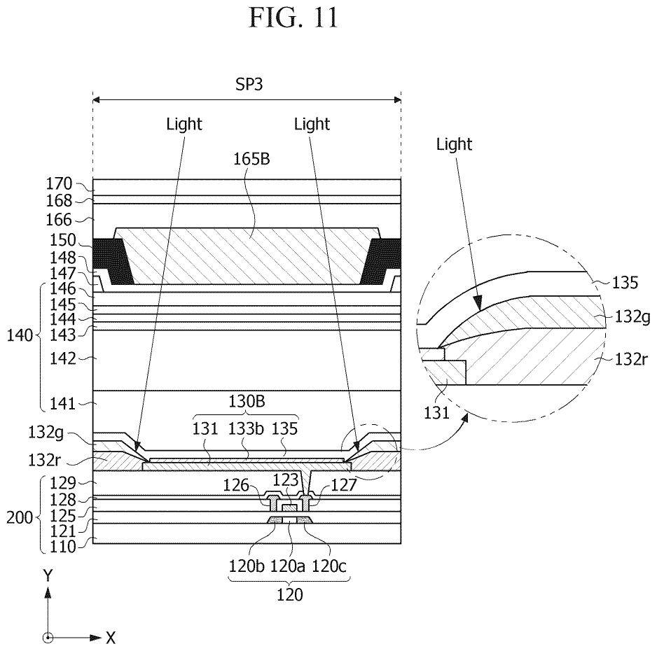

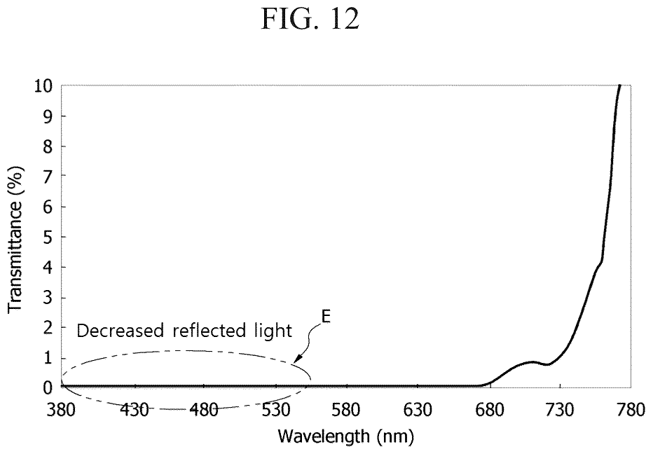

FIG. 11 is a cross-sectional view of a blue sub-pixel region in an organic light emitting display device according to another embodiment of the present specification. FIG. 12 is a graph showing transmittance by wavelength of a pixel defining film (yellow portion) composed of red and green light absorbing portions in an organic light emitting display device according to another embodiment of the present specification.

Referring to FIG. 11, third and second pixel defining films 132-3 and 132-2 may contact both sides of the blue light emitting layer 133b below the blue color filter layer 165B located in the third sub-pixel SP3.

In this regard, the portions of the third pixel defining film 132-3 and second pixel defining film 132-2 in contact with the ends of the blue light emitting layer 133b may include a green light absorbing portion 132g and a red light absorbing portion 132r. The green light absorbing portion 132g and red light absorbing portion 132r may be configured in a vertically stacked structure. For example, the green light absorbing portion 132g may be disposed on the red light absorbing portion 132r.

Referring to FIGS. 11 and 12, light incident through the blue color filter layer 165B proceeds to the blue light emitting element 130B region and may be transmitted to the third pixel defining film 132-3 and second pixel defining film 132-2 located at the side edges of the blue light emitting layer 133b. In this case, light incident through the blue color filter layer 165B contacts the green light absorbing portion 132g and is not reflected from it but transmitted and absorbed into the green light absorbing portion 132g and red light absorbing portion 132r.

Referring to FIG. 12, it may be confirmed that reflected light is reduced as no peak wavelength for transmittance value appears in the blue wavelength range of 380 to 530 nm.

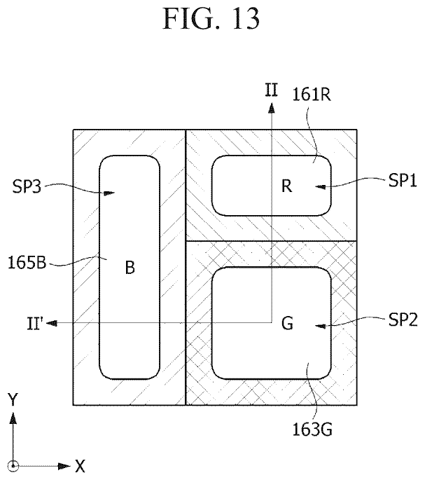

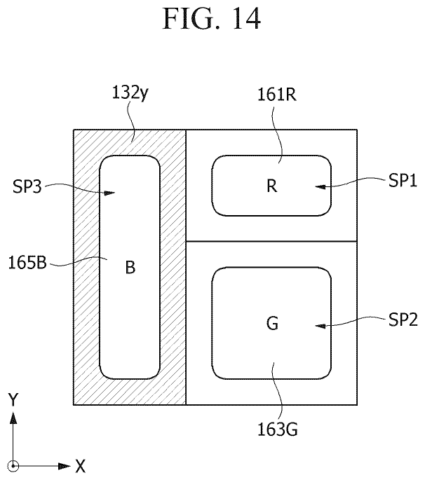

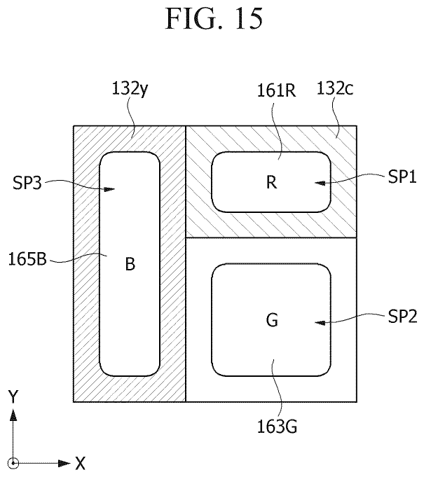

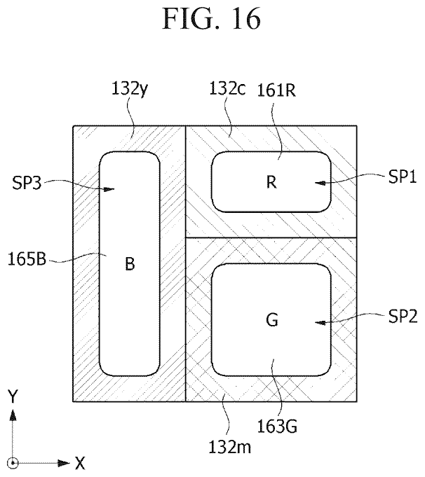

FIG. 13 is a schematic plan view of a plurality of sub-pixels of an organic light emitting display device according to another embodiment of the present specification. FIG. 14 is a plan view showing a first light absorbing portion of a pixel defining film in an organic light emitting display device according to another embodiment of the present specification. FIG. 15 is a plan view showing a first light absorbing portion and a second light absorbing portion of a pixel defining film in an organic light emitting display device according to another embodiment of the present specification. FIG. 16 is a plan view showing a first light absorbing portion, a second light absorbing portion, and a third light absorbing portion of a pixel defining film in an organic light emitting display device according to another embodiment of the present specification.

Referring to FIGS. 13 to 16, an organic light emitting display device according to another embodiment of the present specification may include a plurality of sub-pixels SP1, SP2, and SP3 and first to third pixel defining films 132-1, 132-2, and 132-3 provided in boundary regions between the plurality of sub-pixels SP1, SP2, and SP3.

The plurality of sub-pixels SP1, SP2, and SP3 may include a first sub-pixel SP1 arranged in a first direction, for example, the X-axis direction, a second sub-pixel SP2 arranged in a second direction, for example, the Y-axis, adjacent to the first sub-pixel SP1, and a third sub-pixel SP3 arranged in the first direction, for example, the X-axis direction, adjacent to the first sub-pixel SP1 and the second sub-pixel SP2.

The plurality of sub-pixels SP1, SP2, and SP3 form one unit pixel and may be repeatedly arranged in the first direction and the second direction. However, the arrangement structure of the plurality of sub-pixels SP1, SP2, and SP3 may be changed to various forms known in the art.

In the first sub-pixel SP1, light of a first color, for example, red may be emitted, in the second sub-pixel SP2, light of a second color, for example, green may be emitted, and in the third sub-pixel SP3, light of a third color, for example, blue may be emitted.

Referring to FIGS. 13 to 17, the first pixel defining film 132-1 may be located between the red light emitting element 130R and the green light emitting element 130G. The first pixel defining film 132-1 may include a second light absorbing portion 132c and a third light absorbing portion 132m.

The second light absorbing portion 132c is a cyan light absorbing portion, and the third light absorbing portion 132m may be a magenta light absorbing portion.

Referring to FIGS. 13 to 17, the second pixel defining film 132-2 may be located between the green light emitting element 130G and the blue light emitting element 130B. The second pixel defining film 132-2 may include a first light absorbing portion 132y and a third light absorbing portion 132m. The first light absorbing portion 132y may be a yellow light absorbing portion.

Referring to FIGS. 13 to 17, the third pixel defining film 132-3 may be located between the blue light emitting element 130B and the red light emitting element 130R. The third pixel defining film 132-3 may include a first light absorbing portion 132y and the second light absorbing portion 132c.

Each of the first to third pixel defining films 132-1, 132-2, and 132-3 may include at least two light absorbing portions among the first to third light absorbing portions 132y, 132c, and 132m. However, in the present specification, each of the first to third pixel defining films 132-1, 132-2, and 132-3 is not limited thereto.

The first to third pixel defining films 132-1, 132-2, and 132-3 are provided in boundary regions between the plurality of sub-pixels SP1, SP2, and SP3 to define individual sub-pixel SP1, SP2, and SP3 regions.

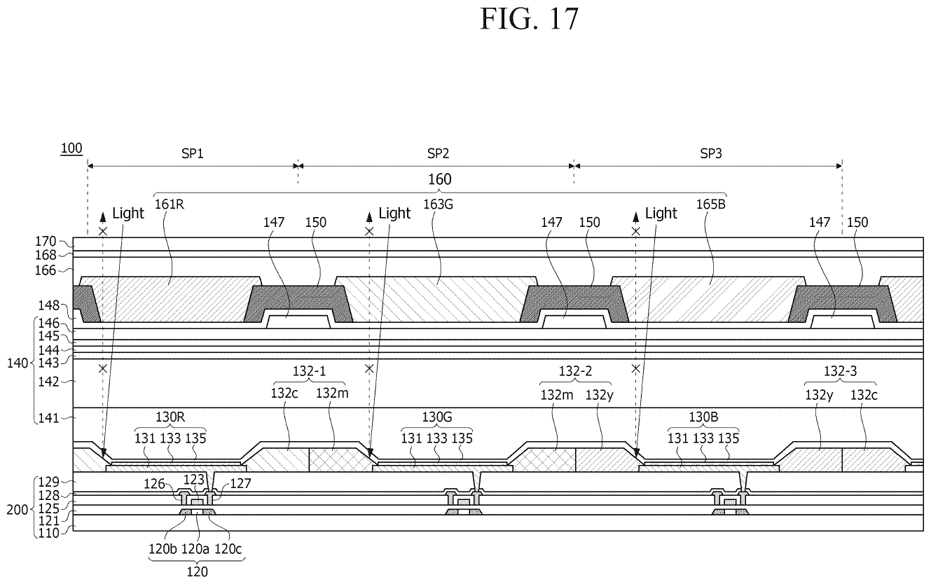

FIG. 17 is a cross-sectional view taken along line II-II′ of FIG. 13, showing a cross-section of an organic electroluminescent display device according to another embodiment of the present specification.

The organic light emitting display device according to another embodiment of the present specification may have the same components as the organic light emitting display device according to the embodiment of the present specification shown in FIG. 5, except for the configuration of the pixel defining film 132.

Specifically, referring to FIG. 17, an organic light emitting display device 100 according to another embodiment of the present specification may include a substrate 110, a circuit element layer 200, a plurality of light emitting elements 130, a pixel defining film 132, an encapsulation layer 140, a black matrix 150, a color filter layer 160, and a cover glass 170.

The circuit element layer 200 may include a passivation layer 128 and a planarization layer 129 provided on the driving thin film transistor. The passivation layer 128 is provided on the source electrode 126 and the drain electrode 127, and the planarization layer 129 may be provided on the passivation layer 128.

The passivation layer 128 and the planarization layer 129 have contact holes, and the first electrode 131 may be connected to the drain electrode 127 through the contact holes. In some cases, the first electrode 131 may be connected to the source electrode 126 through the contact holes.

The circuit element layer 200 may further include various signal wires including gate wires, data wires, power wires, and reference wires, various thin film transistors including switching thin film transistors and sensing thin film transistors, and capacitors, in addition to the driving thin film transistor.

The circuit element layer 200 may further include a passivation layer and a planarization layer provided on the passivation layer to protect the switching thin film transistor, driving thin film transistor, and sensing thin film transistor.

Referring to FIG. 17, the first electrode 131 may function as an anode of the electroluminescent display device, and may be patterned on each of the plurality of sub-pixels SP1, SP2, and SP3, and may be surrounded by the first to third pixel defining films 132-1, 132-2, and 132-3.

The first to third pixel defining films 132-1, 132-2, and 132-3 are provided in boundary regions between the plurality of sub-pixels SP1, SP2, and SP3 to define individual sub-pixel SP1, SP2, and SP3 regions.

A first electrode 131 may be formed for each sub-pixel SP1, SP2, and SP3 on the circuit element layer 200. The first electrode 131 may function as an anode of the organic light emitting display device.

Such a first electrode 131 may include a transparent electrode when the organic light emitting display device according to the present specification is a bottom emission type. When the organic light emitting display device according to the present specification is a top emission type, it may include a reflective electrode.

The pixel defining film 132 is formed to cover both ends of the first electrode 131 on the circuit element layer 200 and may be formed at boundaries between the plurality of sub-pixels SP1, SP2, and SP3.

The pixel defining film 132 may include first to third pixel defining films 132-1, 132-2, and 132-3. Here, the first to third pixel defining films 132-1, 132-2, and 132-3 may be formed by applying yellow, cyan, and magenta color absorbing materials. However, this is not limited thereto.

The first pixel defining film 132-1 may be located between the red light emitting element 130R and the green light emitting element 130G. The first pixel defining film 132-1 may include a second light absorbing portion 132c and a third light absorbing portion 132m. The second light absorbing portion 132c may include a cyan light absorbing portion. The third light absorbing portion 132m may include a magenta light absorbing portion.

The second pixel defining film 132-2 may be located between the green light emitting element 130G and the blue light emitting element 130B. The second pixel defining film 132-2 may include a third light absorbing portion 132m and a first light absorbing portion 132y. The first light absorbing portion 132y may include a yellow light absorbing portion.

The third pixel defining film 132-3 may be located between the blue light emitting element 130B and the red light emitting element 130R. The third pixel defining film 132-3 may include a first light absorbing portion 132y and a second light absorbing portion 132c.

Here, each of the first to third pixel defining films 132-1, 132-2, and 132-3 may include at least two of the first to third light absorbing portions 132y, 132c, and 132m. However, in the present specification, each of the first to third pixel defining films 132-1, 132-2, and 132-3 is not limited thereto.

The first to third pixel defining films 132-1, 132-2, and 132-3 are provided in boundary regions between the plurality of sub-pixels SP1, SP2, and SP3 to define individual sub-pixel SP1, SP2, and SP3 regions.

A light emitting layer 133 may be formed on the first electrode 131 located in the plurality of sub-pixels SP1, SP2, and SP3. The light emitting layer 133 may include a red light emitting layer 133r located in the first sub-pixel SP1, a green light emitting layer 133g located in the second sub-pixel SP2, and a blue light emitting layer 133b located in the third sub-pixel SP3.

Here, the first sub-pixel SP1 is a red sub-pixel, the second sub-pixel SP2 is a green sub-pixel, and the third sub-pixel SP3 may be a blue sub-pixel.

The light emitting layer 133 is disconnected from each other for each of the first to third sub-pixels SP1, SP2, and SP3 by the first to third pixel defining films 132-1, 132-2, and 132-3.

The light emitting layer 133 may include a hole injection layer (HIL), a hole transport layer (HTL), an emission material layer (EML), an electron transport layer (ETL), and an electron injection layer (EIL).

The light emitting layer 133 may include a red light emitting layer 133r, a green light emitting layer 133g, and a blue light emitting layer 133b. The red light emitting layer 133r is located in the red sub-pixel SP1 region, the green light emitting layer 133g is located in the green sub-pixel SP2 region, and the blue light emitting layer 133b may be located in the blue sub-pixel SP3 region.

The red light emitting layer 133r may refer to a light emitting layer of an organic material that emits red light. The green light emitting layer 133g may refer to a light emitting layer of an organic material that emits green light. The blue light emitting layer 133b may refer to a light emitting layer of an organic material that emits blue light.

A second electrode 135 may be formed on the light emitting layer 133. The second electrode 135 may be formed to be continuous without being disconnected in the entire internal region and boundary region of the plurality of sub-pixels SP1, SP2, and SP3.

The second electrode 135 may function as a cathode of the electroluminescent display device. Such a second electrode 135 may be composed of a transparent electrode or semi-transparent electrode when the electroluminescent display device according to the present specification is a top emission type. When the electroluminescent display device according to the present specification is a bottom emission type, it may be composed of a reflective electrode.

An encapsulation layer 140 may be formed on the second electrode 135. The encapsulation layer 140 may serve to prevent external moisture or oxygen from penetrating into the organic light emitting element 130.

The encapsulation layer 140 may include a first passivation layer 141, a first organic insulating layer 142, a second passivation layer 143, a lower buffer layer 144, an insulating material layer 145, and a second organic insulating layer 146. However, the present specification is not limited thereto.

A touch electrode 147 may be formed on the second organic insulating layer 146. The touch electrode 147 may be formed at a position overlapping with the pixel defining film 132.

A second buffer layer 148 covering the touch electrode 147 may be formed on the second organic insulating layer 146.

A black matrix 150 may be formed on the touch electrode 147 located in regions excluding the sub-pixel SP1, SP2, and SP3 regions. The black matrix 150 may be formed in regions between the red color filter layer, green color filter layer, and blue color filter, for example, in boundary regions between the plurality of sub-pixels SP1, SP2, and SP3.

A color filter layer 160 may be disposed in the opening portion of the black matrix 150, for example, on the second buffer layer 148 located in regions of the plurality of sub-pixels.

The color filter layer 160 may include a red color filter layer 161R provided in the first sub-pixel SP1, a green color filter layer 163G provided in the second sub-pixel SP2, and a blue color filter layer 165B provided in the third sub-pixel SP3.

An overcoat layer 166 covering the color filter layer 160 may be formed on the black matrix 150. The overcoat layer 166 may serve to protect internal components from external impact.

A cover glass 170 may be disposed on the overcoat layer 166.

As such, in the present specification, some of the light incident from the outside is transmitted and absorbed into the pixel defining film 132 without being reflected to adjacent sub-pixel regions through the side edges of the red light absorbing portion 132r, green light absorbing portion 132g, and blue light absorbing portion 132b of the pixel defining film 132 located in the boundary region of the sub-pixels SP1, SP2, and SP3, thereby improving color reproduction rate in the sub-pixel regions SP1, SP2, and SP3.

The embodiments of the present invention have been described in more detail with reference to the accompanying drawings, but the present invention is not necessarily limited to these embodiments, and various modifications may be made within the scope without departing from the technical idea of the present invention.

Therefore, the embodiments disclosed in the present invention are not intended to limit the technical idea of the present invention but to illustrate it, and the scope of the technical idea of the present invention is not limited by these embodiments.

Therefore, the embodiments described above should be understood as illustrative in all respects and not restrictive.

The protection scope of the present invention should be interpreted by the claims, and all technical ideas within the equivalent scope should be interpreted as being included in the scope of rights of the present invention.

What is claimed is:

1. An organic light emitting display device comprising:
a substrate;
a circuit element layer disposed on the substrate;
a plurality of pixel defining films disposed on the circuit element layer;
a plurality of light emitting elements disposed between the plurality of pixel defining films and having a first electrode and a light emitting layer, and a second electrode;
an encapsulation layer disposed on the second electrode of the plurality of light emitting elements;
a black matrix disposed on the encapsulation layer and overlapping the plurality of pixel defining films; and
a plurality of color filter layers disposed in opening portion of the black matrix,
wherein the plurality of pixel defining films include a plurality of light absorbing portions.

2. The organic light emitting display device of claim 1, wherein the plurality of light absorbing portions include light absorbing portions of different colors.

3. The organic light emitting display device of claim 1, wherein the plurality of light absorbing portions include:
at least two of a first light absorbing portion, a second light absorbing portion, and a third light absorbing portion.

4. The organic light emitting display device of claim 3, wherein each of the first to third light absorbing portions includes one of a red light absorbing portion, a green light absorbing portion, and a blue light absorbing portion.

5. The organic light emitting display device of claim 3, wherein the first light absorbing portion and the second light absorbing portion constituting the plurality of light absorbing portions have different colors, and
wherein the first light absorbing portion and the second light absorbing portion include one of a yellow light absorbing portion, a cyan light absorbing portion, and a magenta light absorbing portion.

6. The organic light emitting display device of claim 1, wherein the pixel defining films further include a first light absorbing portion and a second light absorbing portion and a third light absorbing portion stacked on the first light absorbing portion.

7. The organic light emitting display device of claim 6, wherein the first light absorbing portion includes a red light absorbing portion, and the second light absorbing portion and the third light absorbing portion include one of a green light absorbing portion and a blue light absorbing portion.

8. The organic light emitting display device of claim 1, wherein the pixel defining films further include a first light absorbing portion and a second light absorbing portion, and a third light absorbing portion disposed on the first light absorbing portion and the second light absorbing portion.

9. The organic light emitting display device of claim 8, wherein the first light absorbing portion is a light absorbing portion of a first color, the second light absorbing portion is a light absorbing portion of a second color, and the third light absorbing portion is a light absorbing portion of a third color.

10. The organic light emitting display device of claim 9, wherein the first color and second color are one of red and green, and the third color is blue.

11. The organic light emitting display device of claim 1, wherein the encapsulation layer includes a plurality of passivation layers, a planarization layer, a plurality of insulating layers, and a plurality of buffer layers.

12. The organic light emitting display device of claim 1, further comprising:
an overcoat layer and a cover glass disposed on the color filter layer.

13. An organic light emitting display device comprising:
a substrate having a plurality of sub-pixel regions;
a plurality of light emitting elements disposed on the substrate located in the plurality of sub-pixel regions; and
a plurality of pixel defining films configured to separate the plurality of light emitting elements,
wherein the plurality of pixel defining films include a plurality of light absorbing portions of different colors.

14. The organic light emitting display device of claim 13, wherein the plurality of light absorbing portions include:
at least two of a first light absorbing portion, a second light absorbing portion, and a third light absorbing portion.

15. The organic light emitting display device of claim 14, wherein each of the first to third light absorbing portions includes one of a red light absorbing portion, a green light absorbing portion, and a blue light absorbing portion.

16. The organic light emitting display device of claim 15, wherein the first light absorbing portion and the second light absorbing portion constituting the plurality of light absorbing portions include one of a yellow light absorbing portion, a cyan light absorbing portion, and a magenta light absorbing portion.

17. The organic light emitting display device of claim 13, wherein the pixel defining film further include a first light absorbing portion and a second light absorbing portion and a third light absorbing portion stacked on the first light absorbing portion.

18. The organic light emitting display device of claim 17, wherein the first light absorbing portion includes a red light absorbing portion, and
wherein the second light absorbing portion and third light absorbing portion include one of a green light absorbing portion and a blue light absorbing portion.

19. The organic light emitting display device of claim 13, wherein the pixel defining films further include a first light absorbing portion and a second light absorbing portion, and a third light absorbing portion disposed on the first light absorbing portion and the second light absorbing portion.

20. The organic light emitting display device of claim 19, wherein the first light absorbing portion is a light absorbing portion of a first color, the second light absorbing portion is a light absorbing portion of a second color, and the third light absorbing portion is a light absorbing portion of a third color.

21. The organic light emitting display device of claim 20, wherein the first color and second color are one of red and green, and the third color is blue.
